(19) United States
(12) Patent Application Publication
(10) Pub. No.: US 2024/0178800 A1
(43) Pub. Date: May 30, 2024

(54) DYNAMIC CONTROL OF FRONT-END STAGE TRANSCONDUCTANCE IN BIPOLAR AMPLIFIERS

(71) Applicant: TEXAS INSTRUMENTS INCORPORATED, Dallas, TX (US)

(72) Inventors: Tyler James Archer, Vail, AZ (US); Bharath Karthik Vasan, Tucson, AZ (US)

(21) Appl. No.: 18/070,985

(22) Filed: Nov. 29, 2022

(51) Int. Cl. H03F 3/04

(52) U.S. Cl. CPC H03F 3/04

(57) ABSTRACT

Examples of circuits, amplifiers and stages thereof include a front-end including an input section having a voltage input and a current output; a current generating section operably coupled to the input section and which produces one or more bias currents to generate a tail current that biases the input section. A signal node, which may be the output terminal of the stage, is operably coupled to the input section. Transconductance choke circuitry is coupled to the signal node and to the current generating section. The transconductance choke circuitry is configured to reduce transconductance of the front-end when the signal at the signal node exceeds an upper threshold or drops below a lower threshold.

### FIELD OF DISCLOSURE

This disclosure relates generally to controlling transconductance at the front end of a bipolar amplifier or stage thereof, and more particularly to circuits in which a transconductance choke is operable to reduce front-end transconductance in response to a targeted signal node voltage being near one or both of the extremes of its dynamic range.

### BACKGROUND

In bipolar amplifiers, signal node voltages need to vary over wide ranges to obtain a desirable large dynamic range. At the same time, component terminal voltages need to be maintained within acceptable operating ranges to avoid degradation of transistor performance due to suboptimal bias conditions. These conflicting objectives can result in undesirable behavior at the extremes of an amplifier's dynamic range.

In an example cross-coupled folded amplifier stage in which the output is defined by the common collector coupling of a PNP transistor and an NPN transistor, when the output voltage is driven to an extreme lower end of its range, the NPN transistor becomes heavily saturated, resulting in undesirable oscillation of the output. When the output voltage is driven to an extreme upper end of its range, the PNP transistor becomes heavily saturated, resulting in injection of current from the isolation well to the base of the PNP transistor through a parasitic NPN comprised of the isolation well, collector, and base of the PNP transistor. This parasitic device current is particularly high in cross-coupled folded stages. This undesirable parasitic device current increases the risk of latch-up.

Some conventional solutions limit the dynamic ranges of signal node voltages, e.g., through clamping, to prevent transistors from experiencing suboptimal bias conditions. This, however, results in undesirably limiting amplifier output voltage range.

A better solution to these issues is desirable, and in this context embodiments of the invention arise.

### SUMMARY

In an example, a circuit comprises a front-end including an input section (e.g., a transconductance section/input transistors) having a voltage input and a current output; a current generating section (e.g., by which one or more bias currents are generated) operably coupled to the input section; a signal node (e.g., where an output voltage is present) operably coupled to the input section; and transconductance choke circuitry coupled to the signal node and to the current generating section. The transconductance choke circuitry is configured to control transconductance of the front-end.

In an example, an amplifier comprises an input section having a voltage input and a current output; a current generating section operably coupled to the input section, the current generating section including impedance circuitry; a signal node operably coupled to the input section; voltage follower circuitry coupled to the signal node; and diode circuitry coupled to the voltage follower circuitry and to the impedance circuitry.

In an example, an amplifier comprises an input section configured to receive an input voltage; an output section configured to output an output voltage in response to the input voltage; and transconductance choke circuitry configured to reduce transconductance of the input section in response to the output voltage exceeding or dropping below a threshold. There may be two thresholds: an upper threshold and a lower threshold. In such an example arrangement, the transconductance choke circuitry may be configured to reduce transconductance of the input section when the output voltage exceeds the upper threshold and when the output voltage drops below the lower threshold.

These and other features will be better understood from the following detailed description with reference to the accompanying drawings.

### BRIEF DESCRIPTION OF THE DRAWINGS

Features of the disclosure may be understood from the following figures taken in conjunction with the detailed description.

FIG. 1 shows a block diagram of a first example of transconductance choke circuitry in a stage of an amplifier to control front-end transconductance.

FIG. 2 shows a circuit diagram of an example stage of an example amplifier including a second example of transconductance choke circuitry to control front-end transconductance.

FIG. 3 shows a circuit diagram of an example stage of an example amplifier including a third example of transconductance choke circuitry to control front-end transconductance.

FIG. 4 shows a circuit diagram of an example stage of an example amplifier including a fourth example of transconductance choke circuitry to control front-end transconductance.

FIG. 5 shows a circuit diagram of an example stage of an example amplifier including a fifth example of transconductance choke circuitry to control front-end transconductance.

FIGS. 6A and 6B show graphs illustrating improvement in loop gain and output voltage behavior using transconductance choke circuitry configured substantially as shown in FIG. 5, when the output voltage is driven to an extreme lower end of its dynamic range.

FIG. 7 shows a graph illustrating reduction in isolation well current and increase in signal dynamic range using the transconductance choke circuitry configured substantially as shown in FIG. 4, when the output voltage is driven to an extreme upper end of its dynamic range.

FIG. 8 is a flow diagram of an example method of controlling front-end transconductance in an example stage of an example amplifier.

### DETAILED DESCRIPTION

Specific examples are described below in detail with reference to the accompanying figures. These examples are not intended to be limiting. In the drawings, corresponding numerals and symbols generally refer to corresponding parts unless otherwise indicated. The objects depicted in the drawings are not necessarily drawn to scale.

Example circuits, amplifiers and stage(s) thereof are provided that sense when a targeted signal node voltage (e.g., a stage output voltage) is near either its high or low extreme, and reduces front-end transconductance in response. This allows transistors to enter suboptimal voltage bias conditions, maximizing the dynamic range of the targeted signal node voltage. Transconductance choke circuitry reduces front-end transconductance by reducing the amount of bias current that flows to the stage's input transistors when the targeted signal node voltage is near either extreme of its range. Reducing front-end transconductance in this manner, instead of limiting the signal node voltage range, avoids, or greatly reduces the likelihood of occurrence of, undesirable signal behavior, such as oscillation or high current in parasitic devices. Terminals of the transconductance choke circuitry are biased to achieve low and high thresholds for triggering transconductance reduction.

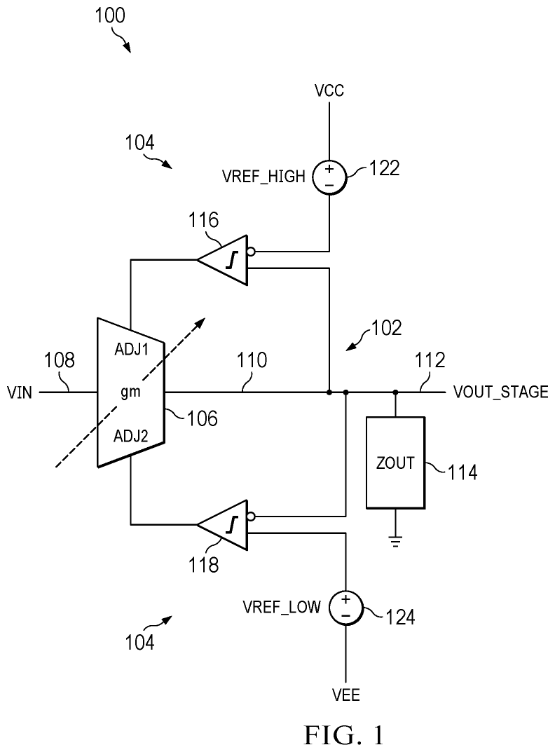

FIG. 1 is a block diagram of a first example of transconductance choke circuitry 104 in a stage 102 of an amplifier 100 to control front-end transconductance. Stage 102 includes a front-end block 106 having an input 108 and an output 110. Input 108 is configured to receive an input voltage (VIN), and in response a current is generated at output 110. Stage 102 has an output (signal) node 112 at which a stage output voltage (VOUT_STAGE) is output in response to VIN. Stage 102 has an output impedance represented by impedance element 114 (ZOUT) coupled between output node 112 and ground.

Example transconductance choke circuitry 104 includes first and second voltage-comparison elements 116 and 118, respectively. One of the inputs of voltage-comparison element 116 is coupled to output node 112, and the other input is coupled to the negative terminal of a high reference voltage 122 (VREF_HIGH), the positive terminal of which is coupled to a first voltage supply terminal of stage 102, which terminal is adapted to be coupled to a first (positive) voltage supply (VCC). The output of voltage-comparison element 116 is coupled to a first adjustment node (ADJ1) of front-end block 106.

Voltage-comparison element 118 is configured similarly with respect to a low reference voltage 124 (VREF_LOW), which is coupled between an input of voltage-comparison element 118 and stage's 102 second voltage supply terminal, which in turn is adapted to be coupled to a second voltage node (VEE), which may be ground or a negative voltage supply. The other input of voltage-comparison element 118 is coupled to output node 112, and the output of voltage-comparison element 118 is coupled to a second adjustment node (ADJ2) of front-end block 106.

High and low reference voltages 122 and 124 set high and low thresholds relative to VCC and VEE, respectively. When VOUT_STAGE crosses one of these thresholds, i.e., exceeds the high threshold or falls below the low threshold and thus comes close to the corresponding supply voltage/node (VCC or VEE), the corresponding voltage-comparison element 116 or 118 asserts an output on the corresponding adjustment node ADJ1 or ADJ2 to reduce the transconductance of front-end block 106. In an example, the output of each of voltage-comparison element 116 and 118 is configured to vary smoothly across its full range through a relatively narrow (˜100-200 mV) VOUT_STAGE range around the corresponding reference voltage.

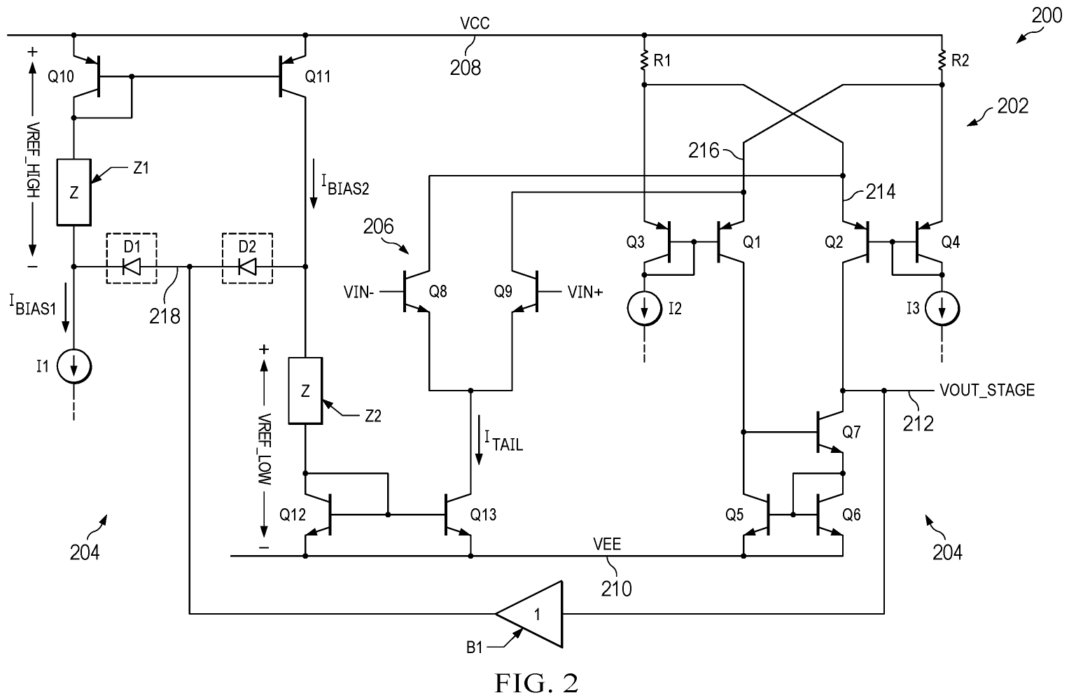

FIG. 2 shows a circuit diagram of an example stage 202 of an example amplifier 200, which may be a multi-stage amplifier. Stage 202 includes a second, more specific, example of the transconductance choke circuitry, identified by reference number 204, to control transconductance of a front-end 206 of stage 202. Front-end 206 includes a pair of input transistors Q8 and Q9, each of which in this example is an n-type bipolar junction transistor (n-BJT). Input transistors Q8 and Q9 are configured to receive a differential input voltage signal (VIN); one component (VIN−) is applied to the base of one of the input transistors (e.g., Q8), and the other component (VIN+) is applied to the base of the other input transistor (e.g., Q9). The emitters of Q8 and Q9 are coupled together and form a path for a tail current I_{TAIL} that biases input transistors Q8 and Q9. The collectors of transistors Q8 and Q9, which form part of the signal path, are coupled to downstream components of stage 202 as described below.

Stage 202 also includes a current generating section, which is generally comprised of transistors Q10-Q13 and current source I1. In the illustrated example, each of Q10 and Q11 is a p-type bipolar junction transistor (p-BJT), and each of Q12 and Q13 is an n-BJT. Transistors Q10 and Q11 form a first current mirror, which is coupled to a first voltage supply terminal 208 and to a second current mirror formed by transistors Q12 and Q13, the emitters of which are coupled to a second voltage supply terminal 210. First and second voltage supply terminals 208 and 210 are adapted to be coupled to high and low voltages, e.g., VCC and VEE, respectively. The collector of transistor Q13 is coupled to the common-emitter coupling of input transistors Q8 and Q9 forming the tail current path. Current source I1 produces bias current I_{BIAS1}, which is the input to the first current mirror (Q10/Q11). Through operation of the first current mirror (Q10/Q11) and the second current mirror (Q12/Q13), mirrored bias current I_{BIAS2} is generated in response to I_{BIAS1}, which in turn results in mirrored current I_{TAIL}.

The collectors of input transistors Q8 and Q9 are coupled to first and second legs 214 and 216, respectively, of a cross-coupled section of stage 202. Leg 214 includes transistor Q2 and resistor R1 coupled between Q2 and VCC supply terminal 208. Leg 216 includes transistor Q1 and resistor R2 coupled between Q1 and VCC supply terminal 208. In the illustrated example, each of Q1 and Q2 is a p-BJT. The base of transistor Q1 is coupled to the common base-collector connection of p-BJT transistor Q3, as well as to a current source I2. The emitter of Q3 is coupled to resistor R1 and to the emitter of Q2. The base of transistor Q2 is coupled to the common base-collector connection of p-BJT transistor Q4, as well as to a current source I3. The emitter of Q4 is coupled to resistor R2 and to the emitter of Q1. The output end of each of current sources I2 and I3 is coupled to an unspecified node, which may be different and which may vary depending on the particular application.

The cross-coupled section further includes n-BJTs Q5, Q6 and Q7, which form a Wilson current mirror. The collector of Q1 is coupled to the collector of Q5 and to the base of Q7. Q5 and Q6 have their emitters coupled to VEE supply terminal 210. The collectors of Q2 and Q7 are coupled together to form output (signal) node 212 at which a stage output voltage (VOUT_STAGE) is output.

Embodied within stage 202 is transconductance choke circuitry 204, which includes a voltage follower B1 having an input coupled to output node 212. The output of voltage follower B1 is coupled to an internal node between a pair of diode elements D1 and D2, which also form part of transconductance choke circuitry 204. Each of diode element D1 and D2 may be a single diode or multiple diodes coupled together, or may be another component or circuit that is configured to function as a diode. Internal node 218 is the coupling between the anode of diode element D1 and the cathode of diode element D2. The cathode of D1 is coupled to the current path in which I_{BIAS1} flows, and the anode of D2 is coupled to the current path in which I_{BIAS2} flows. Transconductance choke circuitry 204 also includes impedance circuitry, which in the example of FIG. 2, is in the form of first and second impedance elements Z1 and Z2, respectively. I_{BIAS1} flowing through Z1 together with the base-emitter voltage drop of transistor Q10 sets the high threshold (VREF_HIGH) relative to VCC. I_{BIAS2} flowing through Z2 together with the base-emitter voltage of transistor Q12 sets the low threshold (VREF_LOW) relative to VEE. VREF_HIGH biases the cathode terminal of diode element D1, and VREF_LOW biases the anode terminal of diode element D2.

In operation, voltage follower B1 produces at its output a tracking voltage that tracks or follows VOUT_STAGE (the targeted signal node voltage) received at the input of voltage follower B1, such that the voltage between B1's output and output node 212 is substantially constant. This tracking voltage output by voltage follower B1 acts on internal node 218 of diode elements D1 and D2 to shunt away a portion of either I_{BIAS1} or I_{BIAS2}. When VOUT_STAGE, plus any voltage shift from the input of B1 to the output of B1, crosses VCC minus VREF_HIGH plus the forward voltage of diode element D1, D1 is forward biased to shunt away a portion of I_{BIAS1}. When VOUT_STAGE, plus any voltage shift from the input of B1 to the output of B1, drops below VREF_LOW minus the forward voltage of diode element D2, D2 is forward biased to shunt away a portion of I_{BIAS2}. The reduction of the portion of one of these bias currents that reaches its corresponding current mirror input (collector of Q10 or collector of Q12), in turn, reduces the input transistor bias current I_{TAIL}, causing a reduction in transconductance of front-end 206 of stage 202.

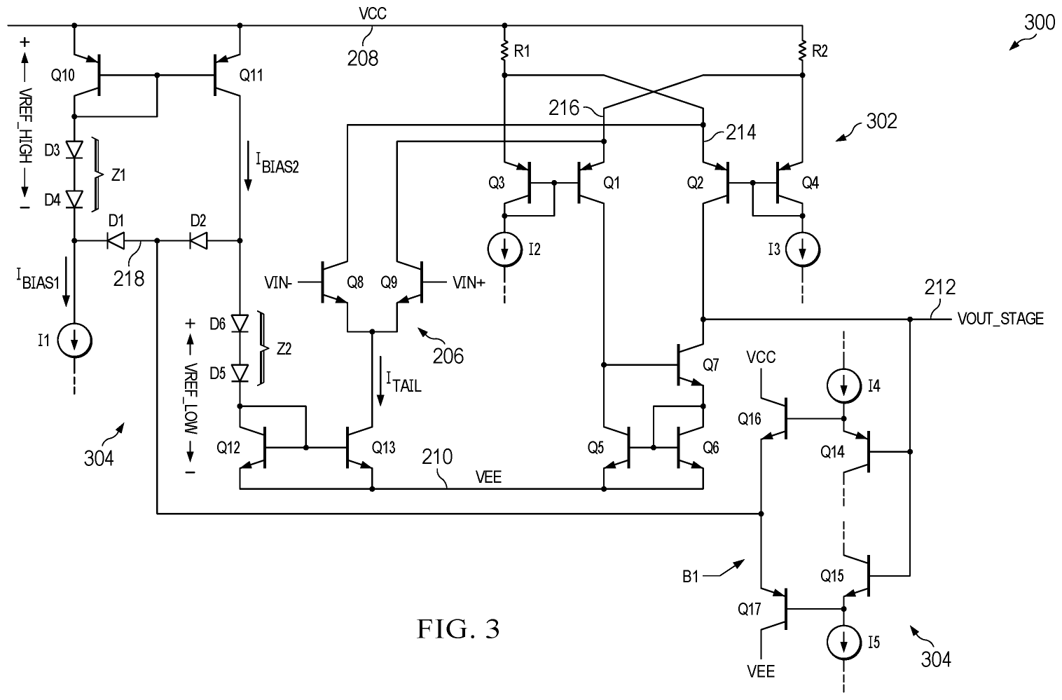

FIG. 3, which is a circuit diagram of an example stage 302 of an example amplifier 300, shows example implementations of impedance elements Z1 and Z2, as well as an example implementation of voltage follower B1, of the transconductance choke circuitry identified by reference numeral 304 in FIG. 3, to control transconductance of front-end 206, which is the same as that in FIG. 2. Other elements/components in FIG. 3 that are the same or substantially the same as those in FIG. 2 are also identified by the same reference numerals/symbols used in FIG. 2.

In this implementation, voltage follower B1 is realized as a diamond buffer comprised of transistors Q14-Q17 and current sources 14 and 15. Diamond buffer B1 may be configured to have approximately zero voltage shift between its input (common base coupling of Q14 and Q15) and its output (common emitter coupling of Q16 and Q17). Each of impedance elements Z1 and Z2 is realized as a 2-diode p-n junction string. The string forming Z1 includes diodes D3 and D4, and the string forming Z2 includes diodes D5 and D6. Each of diode elements D1 and D2 is realized as a single p-n junction diode.

In the configuration of FIG. 3, a portion of a bias current (I_{BIAS1} or I_{BIAS2}) is shunted to a voltage supply/node (e.g., VEE), reducing the transconductance of front-end 206, when:

VOUT_STAGE<VEE+V_{BE-Q12}+V_{D5}+V_{D6}−VD₂ or

VOUT_STAGE>VCC−V_{EB-Q10}−V_{D3}−V_{D4}+V_{D1},
where V_{D}n, is the forward voltage of diode Dn, V_{BE-Qn} is the base-emitter voltage of n-BJT Qn, and V_{EB-Qn} is the emitter-base voltage of p-BJT Qn.

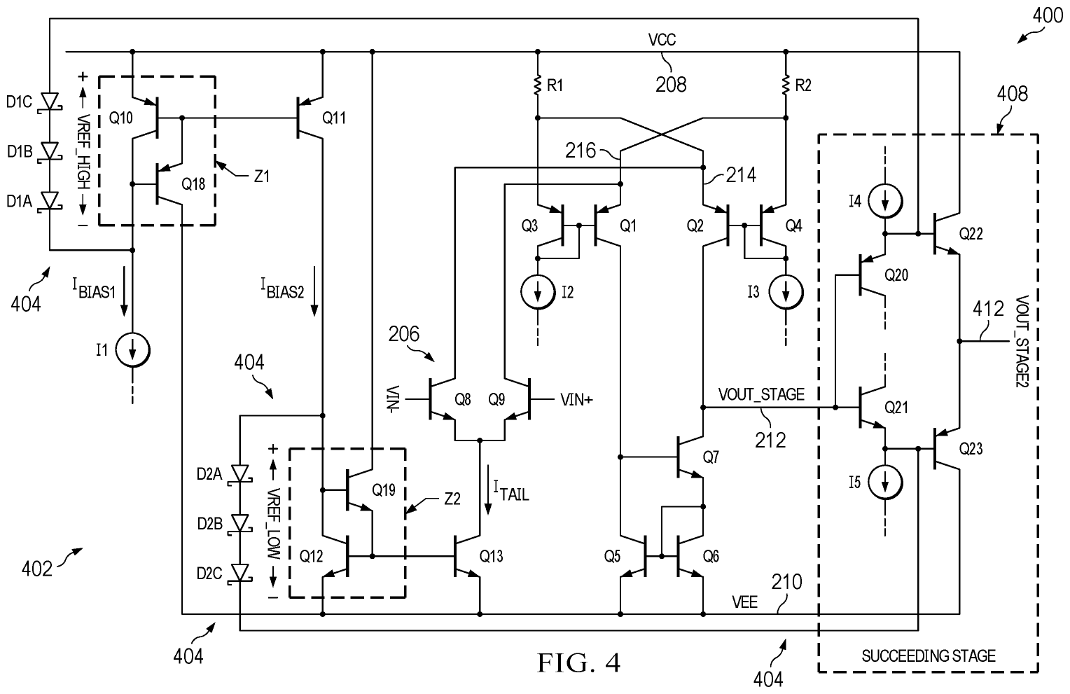

In the configuration of FIG. 4, impedance elements Z1 and Z2 of transconductance choke circuitry 404 are realized by adding beta helper transistors Q18 and Q19 to the Q10/Q11 current mirror and Q12/Q13 current mirror, respectively. Q18, which is a p-BJT in the illustrated example, is coupled between the base and collector of Q10 and also to VEE supply terminal 210. Q19, which is an n-BJT in the illustrated example, is coupled between the base and collector of Q12 and also to VCC supply terminal 208. Thus, first impedance element Z1 is formed by the Q10/Q18 circuit, and second impedance element Z2 is formed by the Q12/Q19 circuit.

Moreover, in example stage 402 of example amplifier 400, diode elements D1 and D2 of transconductance choke circuitry 404 are realized as Schottky diode series strings D1A-D1B-D1C and D2A-D2B-D2C, respectively. Still further, each Schottky diode series string is responsive to a separate voltage follower p-BJT Q20/current source I4 and n-BJT Q21/current source I5. In the illustrated example, these voltage followers (Q20/I4 and Q21/I5) are integrated into a succeeding stage 408 of amplifier 400, and may be integrated into a diamond buffer of succeeding stage 408, which diamond buffer further comprises n-BJT Q22 and p-BJT Q23. The output of voltage follower Q20/I4 is the emitter of Q20, which is coupled to Schottky diode string D1A-D1B-D1C, and the output of voltage follower Q21/I5 is the emitter of Q21, which is coupled to Schottky diode string D2A-D2B-D2C. With this configuration, the emitters of Q20 and Q21 follow VOUT_STAGE. Moreover, although the voltage followers may be integrated into a buffer in succeeding stage 408, such stage need not be a buffer itself, it may have a gain of greater than 1.

The collectors of transistors Q22 and Q23 are coupled to VCC supply terminal 208 and VEE supply terminal 210, respectively. The emitters of Q22 and Q23 are coupled together to form output 412 of succeeding stage 408, where voltage signal VOUT_STAGE2 is output. Other elements/components in FIG. 4 that are the same or substantially the same as those in FIG. 2 are identified by the same reference numerals/symbols used in FIG. 2.

The transconductance (gm) of front-end 206 is proportional to the magnitude of I_{TAIL}. Absent intervention from transconductance choke circuitry 404, I_{TAIL} is the product of I_{BIAS2} and the gain of the Q12/Q13 current mirror. I_{BIAS2} is the product of constant current I_{BIAS1} (from current source I1) and the gain of the Q10/Q11 current mirror. Therefore, I_{TAIL} is the product of I_{BIAS1} and the two current mirror gains.

If VOUT_STAGE gets too close to VEE, D2A/D2B/D2C turns on, shunting away part of I_{BIAS2} so that it does not reach the Q12/Q13 current mirror. This reduces I_{TAIL} to the product of the remainder of I_{BIAS2} and the Q12/Q13 mirror gain. Transconductance of front-end 206 is thus reduced. If VOUT_STAGE gets too close to VCC, D1A/D1B/D1C turns on, shunting away part of I_{BIAS1} so that it does not reach the Q10/Q11 current mirror. This reduces I_{BIAS2} to the product of the remainder of I_{BIAS1} and the Q10/Q11 mirror gain. Since I_{BIAS2} is reduced, I_{TAIL} is reduced. The transconductance of front-end 206 is thus reduced.

In the configuration of FIG. 4, a portion of a bias current (I_{BIAS1} or I_{BIAS2}) is shunted to a voltage supply/node (e.g., VEE), reducing the transconductance of front-end 206, when:

VOUT_STAGE<VEE+V_{BE-Q12}+V_{BE-Q19}−V_{D2A}−V_{D2B}−V_{D2C}+V_{BE-Q21} or

VOUT_STAGE>VCC−V_{EB-Q10}−V_{EB-Q18}+V_{D1A}+V_{D1B}+V_{D1C}−V_{EB-Q20}.

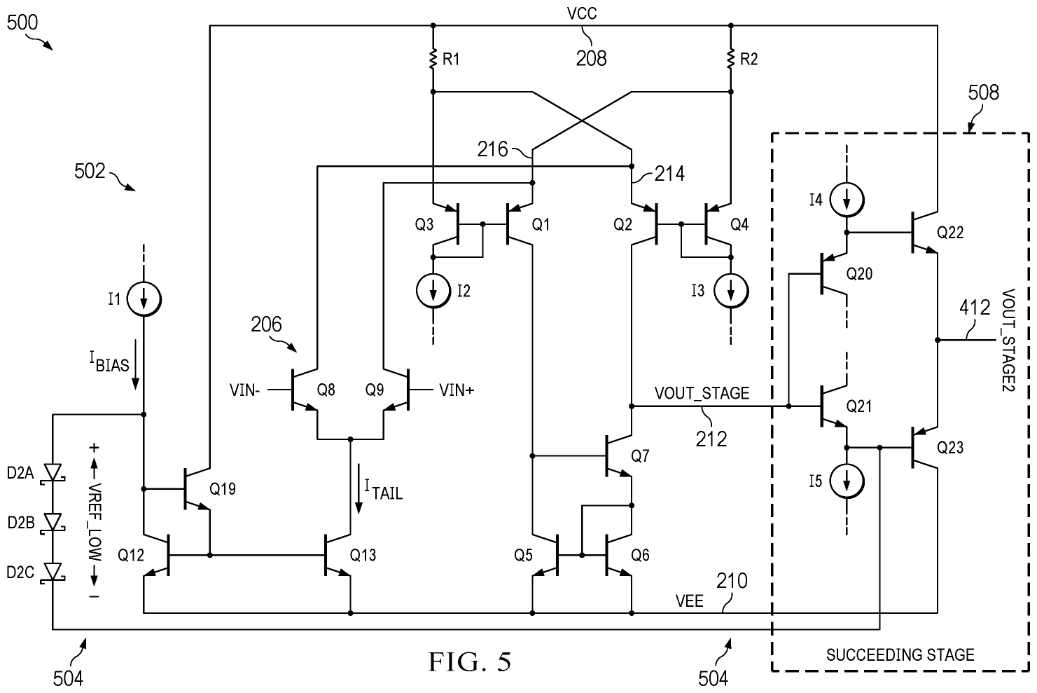

FIG. 5 shows an example stage 502 of an example amplifier 500, which is similar to the configuration shown in FIG. 4, except that the configuration of FIG. 5 implements only the low-side portion of the transconductance choke circuitry identified by 504 in FIG. 5. Thus, diode string D1A-D1B-D1C is omitted, as are transistors Q10, Q11 and Q18. Also, current source I1 is coupled to the collector of Q12 and to the base of Q19 to generate a single bias current I_{BIAS}, which is mirrored to generate I_{TAIL}. The configuration of FIG. 5 may be used when the process technology of amplifier 500 is not susceptible to latch-up resulting from current in Q2's parasitic devices. Transconductance of front-end 206 is thus reduced when VOUT_STAGE falls below VREF_LOW minus the forward voltage of diode string D2A-D2B-D2C plus the base-emitter voltage of Q21. Other elements/components in FIG. 5 common to those in FIG. 4 are identified by the same reference numerals/symbols used in FIG. 4.

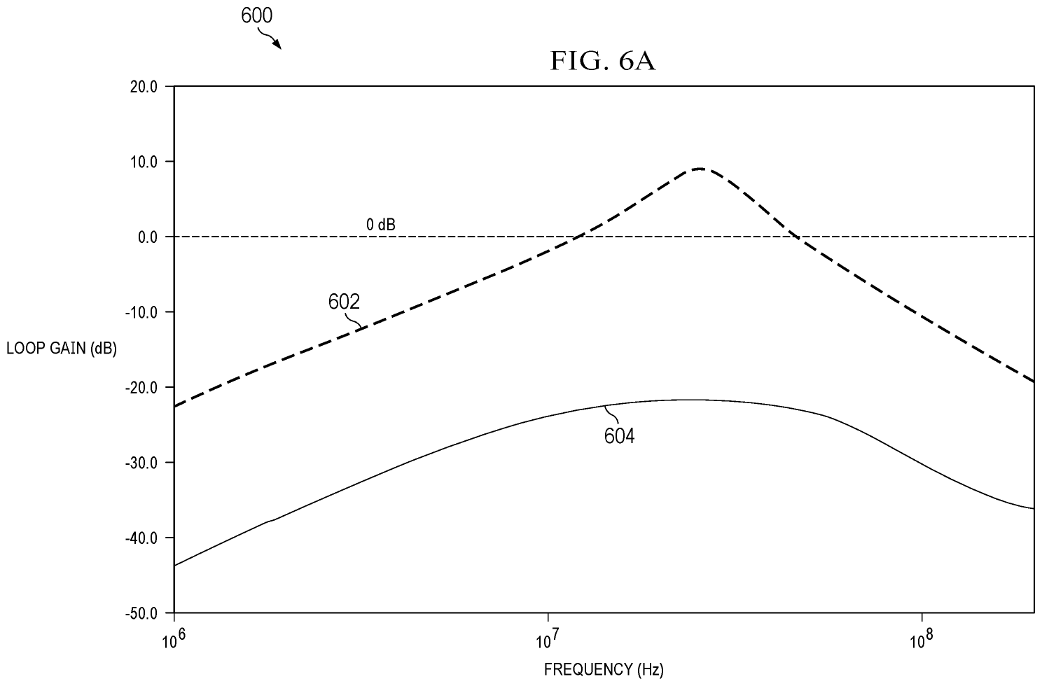

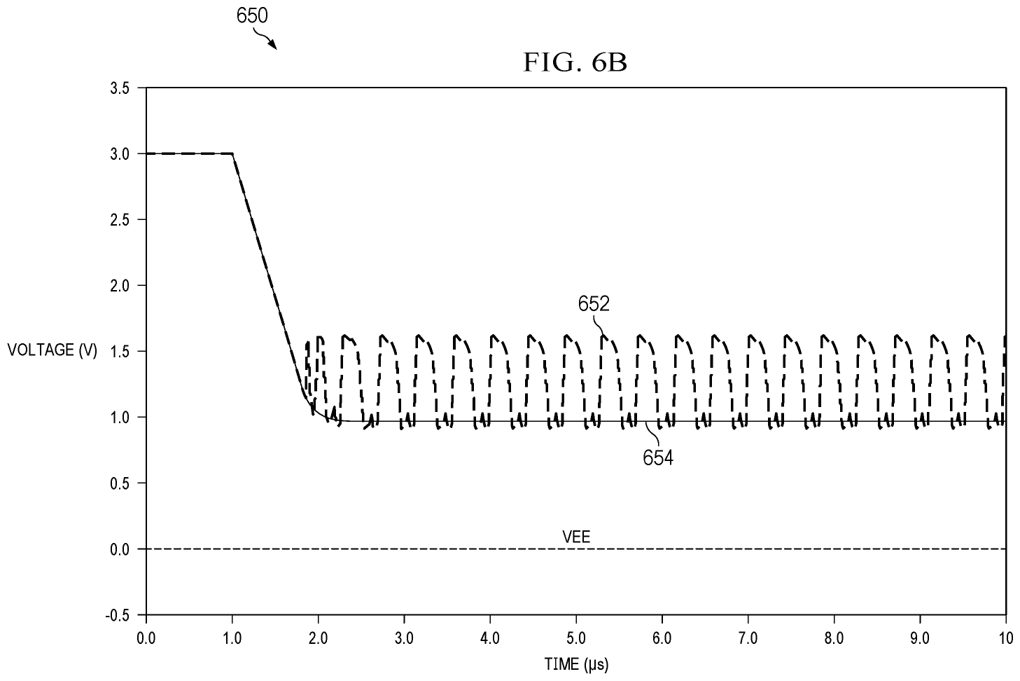

FIGS. 6A and 6B show graphs 600 and 650 illustrating improvement in loop gain and output voltage behavior, respectively, using transconductance choke circuitry configured substantially as shown in FIG. 5, when the output voltage (VOUT_STAGE) is driven to an extreme lower end of its dynamic range, and Wilson mirror cascode transistor Q7 is heavily saturated. In graph 600 of FIG. 6A, curve 602 shows loop gain (dB) with respect to frequency (Hz) without any transconductance choke circuitry. With transconductance choke circuitry 504, indicated by curve 604, loop gain is maintained below 0 dB across a relatively wide frequency range, avoiding instability in this high phase delay condition. In graph 650 of FIG. 6B, VOUT_STAGE (V) without transconductance choke circuitry (curve 652) is rapidly driven down in a period of about 1 μs from about 3 V to a 1-1.5 V range, where VOUT_STAGE oscillates. Driving down VOUT_STAGE in the same manner but with transconductance choke circuitry 504 results in a smooth transition in which VOUT_STAGE settles at about 1 V, as shown by curve 654. As can be seen from graph 650, transconductance choke circuitry 504 eliminates or greatly reduces oscillation in VOUT_STAGE at the extreme lower end, i.e., approximately 1 V, where VEE is ground (approximately zero volts).

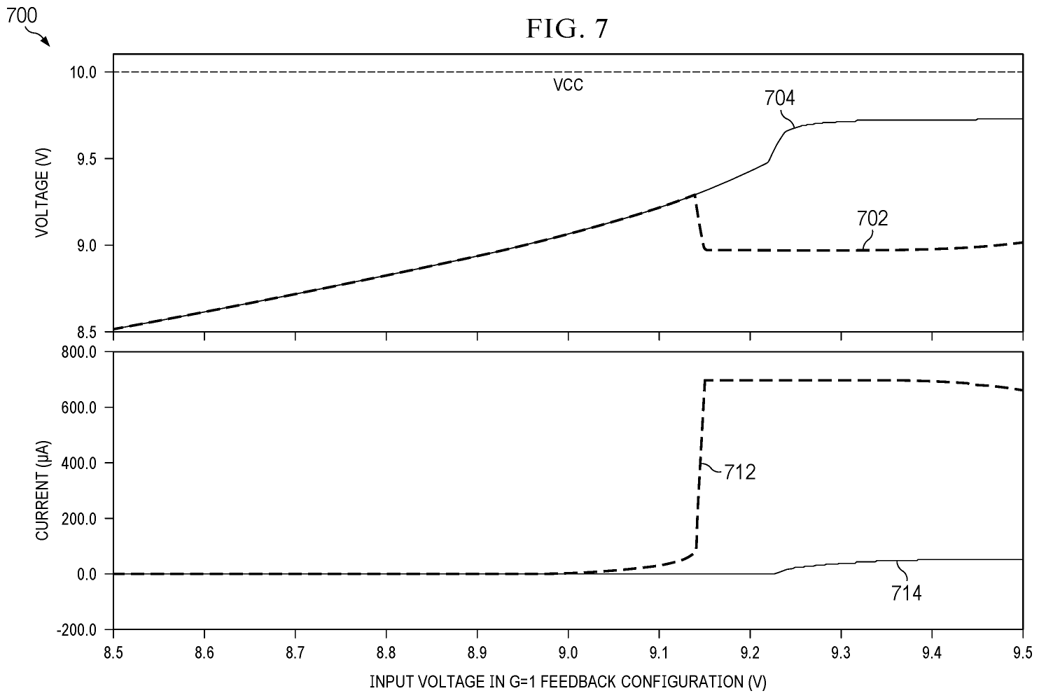

FIG. 7 shows a graph 700 illustrating reduction in isolation well current using the transconductance choke circuitry configured substantially as shown in FIG. 4, when the output voltage is driven to an extreme upper end of its dynamic range. The output voltage VOUT_STAGE (V) is shown as a function of input voltage (V) with no transconductance choke circuitry (curve 702) and with transconductance choke circuitry 404 (curve 704). Also shown is isolation well current (μA) as a function of input voltage (V) with no transconductance choke circuitry (curve 712) and with transconductance choke circuitry (curve 714). With stage 402 coupled to a VCC supply of approximately 10 V, VOUT_STAGE is driven to the extreme upper end of its dynamic range, and signal mirror p-BJT Q2 becomes heavily saturated. When VOUT_STAGE reaches approximately 9.25 V, transconductance choke circuitry 404 reduces the emitter current of Q2, reducing current in the isolation well, which mitigates the risk of latch-up. The voltage drop across resistor R1 is also reduced, extending the dynamic range of VOUT_STAGE.

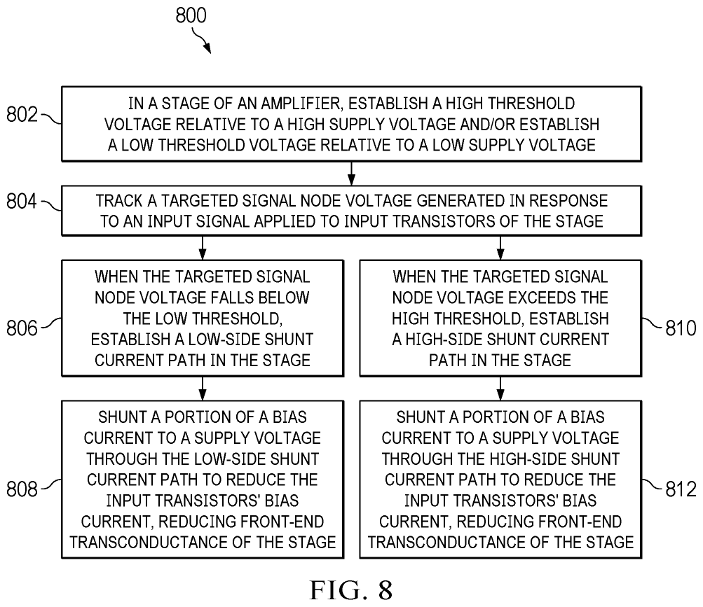

FIG. 8 is a flow diagram of an example method 800 of operating example transconductance choke circuitry in an example amplifier stage. In the amplifier stage, in operation 802, a high threshold voltage is established relative to a high supply voltage and/or a low threshold voltage is established relative to a low supply voltage. During operation of the amplifier stage, a targeted signal node voltage, e.g., the stage output voltage, which is generated in response to an input signal applied to input transistors, is tracked (operation 804). The targeted signal node voltage may be tracked at both its high and low ends, or just tracked at one end, e.g., the low end. When tracking at both ends, the transconductance choke circuitry includes both high- and low-side choke components (e.g., the circuit configurations of FIGS. 1-4), and when tracking at just one end only choke components for such tracking need to be included. For example, when only low-end tracking is needed, the circuit configuration of FIG. 5 may be used. Thus, method 800 may continue to operation 806 only, operation 810 only, or to both such operations.

In operation 806, when the targeted signal node voltage falls below the low threshold, a low-side shunt current path is established in the stage. With reference to FIG. 3, the low-side shunt current path may be through diode element D2, into diamond buffer B1, and out to VEE. With the low-side shunt current path established, in operation 808, a portion of a bias current, e.g., I_{BIAS2}, is shunted, which in turn, reduces the input transistors' bias current I_{TAIL}, thus reducing front-end transconductance of the stage.

In operation 810, when the targeted signal node voltage exceeds the high threshold, a high-side shunt current path is established in the stage. With reference to FIG. 3, the high-side shunt current path may be from VCC, into diamond buffer B1, and through diode element D1. With the high-side shunt current path established, in operation 812, a portion of a bias current, e.g., I_{BIAS1}, is shunted, which in turn, reduces the input transistors' bias current I_{TAIL}, thus reducing front-end transconductance of the stage.

FIG. 8 depicts one possible scenario of operations. Not all operations need necessarily be performed in the order described. Some operations may be combined into a single operation. Some operations, e.g., operations 806, 808, 810 and 812, may be performed multiple times during operation. Additional operations and/or alternative operations may be performed.

Various examples of circuits, amplifiers, and stage(s) thereof include transconductance choke circuitry to reduce transconductance of the front-end of an amplifier stage when a signal node voltage of the stage, e.g., its output voltage, exceeds a high threshold or drops below a low threshold, each of which is set with respect to a corresponding high or low voltage rail, e.g., VCC and VEE. Reducing front-end transconductance under these conditions advantageously prevents, or greatly reduces the likelihood of occurrence of, undesirable amplifier behavior, such as output voltage oscillation and/or high current in parasitic devices when the signal voltage reaches either of its extremes. Such transconductance reduction also increases or maximizes output voltage dynamic range by allowing transistors to be operated deep in suboptimal voltage bias conditions.

Solutions provided herein have broad applications in bipolar amplifiers in which front-end transconductance depends on the magnitude(s) of bias current(s). Solutions provided herein are thus particularly well suited for bipolar amplifiers with different-pair inputs.

Resistance values of various resistors described herein may vary depending on the particular application of the circuit. The supply voltage(s), e.g., VCC and VEE, of the various circuits described herein may any suitable voltage for the particular application. In some examples, VEE may be ground. The current delivered by any of the current sources described herein may be set based on the particular function to be performed. Unless otherwise stated, “about,” “approximately,” or “substantially” with respect to a value means+/−10 percent of the stated value.

As used herein, the terms “terminal” and “node” may be an interconnection, lead and/or pin. Unless specifically stated to the contrary, these terms generally mean an interconnection between or a terminus of a device element, a circuit element, an integrated circuit, a device or other electronic or semiconductor component. The term “control terminal” as used herein refers to the base of an associated BJT, and the term “current terminal” refers to a collector or emitter of an associated BJT.

While the use of bipolar junction transistors (BJTs) is described herein, other types of transistors (or equivalent devices) may be used instead. For example, in some instances an n-type metal-oxide-silicon field-effect transistor (MOSFET) may be used in place of an n-BJT, and in some instances a p-type MOSFET may be used in place of p-BJT. In general, in substituting a MOSFET for a BJT, an n-type BJT would be replaced by an n-type MOSFET and a p-type BJT would be replaced by a p-type MOSFET, in which the emitter would correspond to the source, the collector would correspond to the drain, and the base would correspond to the gate.

The term “couple” is used throughout the specification. The term and derivatives thereof may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

A device that is “configured to” perform a task or function may be configured (i.e. programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors), and/or one or more sources (such as voltage and/or current sources) may instead include only the semiconductor elements within a single physical device (i.e. a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. Circuits described herein are reconfigurable to include the replaced components to provide functionality at least partially similar to functionality available prior to the component replacement.

Modifications of the described examples are possible, as are other examples, within the scope of the claims. Moreover, features described herein may be applied in other environments and applications consistent with the teachings provided.

What is claimed is:

1. A circuit comprising:
a front-end including an input section having a voltage input and a current output;
a current generating section operably coupled to the input section;
a signal node operably coupled to the input section; and
transconductance choke circuitry coupled to the signal node and to the current generating section, the transconductance choke circuitry configured to control transconductance of the front-end.

2. The circuit of claim 1, wherein the transconductance choke circuitry includes:
a first voltage-comparison element having a first reference voltage input and a first signal voltage input, the first signal voltage input coupled to the signal node, the first voltage-comparison element having a first output coupled to the transconductance choke circuitry; and
a second voltage-comparison element having a second reference voltage input and a second signal voltage input, the second signal voltage input coupled to the signal node, the second voltage-comparison element having a second output coupled to the transconductance choke circuitry.

3. The circuit of claim 2, further comprising:
a first reference voltage source coupled between a first voltage supply terminal of the circuit and the first reference voltage input; and
a second reference voltage source coupled between a second voltage supply terminal of the circuit and the second reference voltage input.

4. The circuit of claim 2, wherein the first output of the first voltage-comparison element is coupled to a first adjustment terminal of the transconductance choke circuitry, and the second output of the second voltage-comparison element is coupled to a second adjustment terminal of the transconductance choke circuitry.

5. The circuit of claim 1, wherein the transconductance choke circuitry includes:
a voltage follower having and input and an output, the input coupled to the signal node;
an internal node coupled to the output of the voltage follower;
a first diode element having an anode coupled to the internal node and a cathode coupled to a first node of the current generating section; and
a second diode element having an anode coupled to a second node of the current generating section and a cathode coupled to the internal node.

6. The circuit of claim 5, wherein the transconductance choke circuitry further includes:
a first impedance element coupled to the cathode of the first diode element;
a second impedance element coupled to the anode of the second diode element.

7. The circuit of claim 6, wherein each of the first and second impedance elements is comprised of a plurality of series-coupled diodes.

8. The circuit of claim 5, wherein the voltage follower is configured as a diamond buffer, the coupling of the output of the buffer to the internal node providing a current shunt path.

9. An amplifier comprising:
an input section having a voltage input and a current output;
a current generating section operably coupled to the input section, the current generating section including impedance circuitry;
a signal node operably coupled to the input section;
voltage follower circuitry coupled to the signal node; and
diode circuitry coupled to the voltage follower circuitry and to the impedance circuitry.

10. The amplifier of claim 9, wherein the diode circuitry includes a plurality of Schottky diodes coupled in series.

11. The amplifier of claim 9, wherein the impedance circuitry includes a pair of transistors of the current generating circuitry.

12. The amplifier of claim 11, wherein the pair of transistors includes a first n-type bipolar junction transistor (n-BJT) and a second n-BJT, each having a base, an emitter and a collector, the collector of the first n-BJT coupled to the base of the second n-BJT and the base of the first n-BJT coupled to the emitter of the second n-BJT.

13. The amplifier of claim 9, wherein the amplifier includes multiple stages including:
a first stage comprised of the input section, the current generating section, the signal node, the diode circuitry, and the impedance circuitry, the signal node forming an output of the first stage, and the diode circuitry including first and second diode circuits; and
a second stage having first and second nodes that follow an output voltage at the signal node, the first node coupled to the first diode circuit and the second node coupled to the second diode circuit.

14. The amplifier of claim 13, wherein the succeeding stage includes first and second voltage followers, the diode circuitry includes first and second diode strings, and the impedance circuitry includes first and second impedance circuits, the first impedance circuit formed by a first transistor pair of the current generating section and the second impedance circuit formed by a second transistor pair of the current generating section.

15. The amplifier of claim 14, wherein:
the first voltage follower includes a p-type bipolar junction transistor (p-BJT) and a first current source coupled to the emitter of the p-BJT, the emitter of the p-BJT forming the first node of the second stage, and the second voltage follower includes an n-type bipolar junction transistor (n-BJT) and a second current source coupled to the emitter of the n-BJT, the emitter of the n-BJT forming the second node of the second stage, the bases of the p-BJT and the n-BJT coupled together and to the signal node.

16. The amplifier of claim 15, wherein:
the first diode string includes a first plurality of Schottky diodes coupled in series, one end of which is coupled to the emitter of the p-BJT of the first voltage follower and the other end of which is coupled to the first transistor pair forming the first impedance circuit; and
the second diode string includes a second plurality of Schottky diodes coupled in series, one end of which is coupled to the emitter of the n-BJT of the second voltage follower and the other end of which is coupled to the second transistor pair forming the second impedance circuit.

17. The amplifier of claim 16, wherein the current generating section includes a third current source coupled to the first transistor pair.

18. An amplifier comprising:
an input section configured to receive an input voltage;
an output section configured to output an output voltage in response to the input voltage; and
transconductance choke circuitry configured to reduce transconductance of the input section in response to the output voltage exceeding or dropping below a threshold.

19. The amplifier of claim 18, further comprising:
current mirror circuitry having a first current source configured to generate a bias current and in response produce a tail current in the input section to bias the input section,
wherein the transconductance choke circuitry is configured to reduce transconductance of the input section by reducing the tail current.

20. The amplifier of claim 19, wherein the transconductance choke circuitry includes at least one diode and a transistor integrated into the current mirror circuitry, the transconductance choke circuitry configured to track the output voltage and output a tracking signal, the at least one diode being responsive to the tracking signal.

21. The amplifier of claim 18, wherein the threshold includes an upper threshold and a lower threshold, the transconductance choke circuitry configured to reduce transconductance of the input section when the output voltage exceeds the upper threshold and when the output voltage drops below the lower threshold.

22. The amplifier of claim 21, further comprising:
current mirror circuitry having a first current source configured to generate a first bias current, and in response, produce a second bias current in the current mirror circuitry to produce a tail current in the input section to bias the input section,
wherein the transconductance choke circuitry is configured to reduce transconductance of the input section by reducing the tail current.

23. The amplifier of claim 22, wherein:
the upper threshold is established relative to a high supply voltage by the first bias current flowing through a first structure formed by the transconductance choke circuitry and the current mirror circuitry; and
the lower threshold is established relative to a low supply voltage by the second bias current flowing through a second structure formed by the transconductance choke circuitry and the current mirror circuitry.

24. The amplifier of claim 23, further comprising:
voltage follower circuitry configured to track the output voltage and output a tracking signal, the transconductance choke circuitry responsive to the tracking signal.

25. The amplifier of claim 23, wherein the current mirror circuitry and transconductance choke circuitry are configured to establish:
a high-side shunt current path in response to the output voltage exceeding the upper threshold to reduce the first bias current; and
a low-side shunt current path in response to the output voltage dropping below the lower threshold to reduce the second bias current.
